(19) United States
(12) Patent Application Publication
(10) Pub. No.: US 2025/0203985 A1
(43) Pub. Date: Jun. 19, 2025

(54) SILICON CARBIDE SUBSTRATE, SILICON CARBIDE EPITAXIAL SUBSTRATE, AND METHOD OF MANUFACTURING SILICON CARBIDE SEMICONDUCTOR DEVICE

(71) Applicant: SUMITOMO ELECTRIC INDUSTRIES, LTD., Osaka (JP)

(72) Inventors: Takahiro SHIIHARA, Osaka (JP); Naoki KAJI, Osaka (JP); Shunsaku UETA, Osaka (JP); Kyoko OKITA, Osaka (JP)

(73) Assignee: SUMITOMO ELECTRIC INDUSTRIES, LTD., Osaka (JP)

(21) Appl. No.: 18/860,672

(22) PCT Filed: Apr. 27, 2023
(86) PCT No.: PCT/JP2023/016669

§ 371 Date: Oct. 27, 2024

(30) Foreign Application Priority Data
Jun. 2, 2022 (JP) 2022-090216

(51) Int. Cl. H10D 62/832; C30B 25/20; C30B 29/36; H10D 62/60

(52) U.S. Cl. CPC H10D 62/8325; C30B 25/20; C30B 29/36; H10D 62/60

(57) ABSTRACT

A silicon carbide substrate has a first main surface and a second main surface opposite to the first main surface. One or more first voids are present in the first main surface. An area density of the first voids is less than 0.9/cm². When viewed in a direction perpendicular to the first main surface, the first void has a width of 10 μm or more and 100 μm or less. When viewed in a direction parallel to the first main surface, the width of the first void increases from the first main surface toward the second main surface. When viewed in the direction parallel to the first main surface, the first void has a depth smaller than a thickness of the silicon carbide substrate. The first main surface is a carbon plane, or a plane inclined at an off angle of 8° or less relative to the carbon plane.

### TECHNICAL FIELD

The present disclosure relates to a silicon carbide substrate, a silicon carbide epitaxial substrate, and a method of manufacturing a silicon carbide semiconductor device. The present application claims priority based on Japanese Patent Application No. 2022-090216 filed on Jun. 2, 2022, the entire contents of which are incorporated herein by reference.

### BACKGROUND ART

Japanese National Patent Publication No. 2010-514648 (PTL 1) describes a method of manufacturing a silicon carbide crystal.

### CITATION LIST

### Patent Literature

PTL 1: Japanese National Patent Publication No. 2010-514648

### SUMMARY OF INVENTION

A silicon carbide substrate according to the present disclosure has a first main surface and a second main surface opposite to the first main surface. One or more first voids are present in the first main surface. An area density of the first voids is less than 0.9/cm². When viewed in a direction perpendicular to the first main surface, the first void has a width of 10 μm or more and 100 μm or less. When viewed in a direction parallel to the first main surface, the width of the first void increases from the first main surface toward the second main surface. When viewed in the direction parallel to the first main surface, the first void has a depth smaller than a thickness of the silicon carbide substrate. The first main surface is a carbon plane, or a plane inclined at an off angle of 8° or less relative to the carbon plane.

### BRIEF DESCRIPTION OF DRAWINGS

FIG. 1 is a schematic plan view showing a configuration of a silicon carbide substrate according to the present embodiment.

FIG. 2 is a schematic cross-sectional view along a line II-II shown in FIG. 1.

FIG. 3 is an enlarged plan view of a region III shown in FIG. 1.

FIG. 4 is a schematic cross-sectional view along a line IV-IV shown in FIG. 3.

FIG. 5A is an enlarged schematic cross-sectional view of a region VA shown in FIG. 4.

FIG. 5B is an enlarged schematic cross-sectional view of a region VB shown in FIG. 4.

FIG. 6 is a perspective plan view showing a configuration of a first cuboid region.

FIG. 7 is a perspective plan view showing a configuration of a second cuboid region.

FIG. 8 is an enlarged schematic plan view of a second main surface.

FIG. 9 is an enlarged schematic cross-sectional view of a region IX shown in FIG. 4.

FIG. 10 is a schematic plan view showing a first main surface that has been divided into a plurality of square regions.

FIG. 11A is a schematic partial cross-sectional view showing a configuration of an apparatus for manufacturing a silicon carbide crystal according to the present embodiment.

FIG. 11B is a schematic diagram showing a relation between temperature and time in a step of firing a crucible and a graphite member placed in the crucible.

FIG. 12 is a schematic cross-sectional view showing a step of placing a silicon carbide source material and a seed substrate in the crucible.

FIG. 13 is a schematic cross-sectional view showing a step of growing a silicon carbide crystal.

FIG. 14 is an enlarged schematic diagram showing a configuration of a region XIV shown in FIG. 13.

FIG. 15 is a flowchart schematically showing a method of manufacturing a silicon carbide semiconductor device according to the present embodiment.

FIG. 16 is a schematic cross-sectional view showing a configuration of a silicon carbide epitaxial substrate according to the present embodiment.

FIG. 17 is a schematic cross-sectional view showing a step of forming a body region.

FIG. 18 is a schematic cross-sectional view showing a step of forming a source region.

FIG. 19 is a schematic cross-sectional view showing a step of forming a trench in a third main surface of a silicon carbide epitaxial layer.

FIG. 20 is a schematic cross-sectional view showing a step of forming a gate insulating film.

FIG. 21 is a schematic cross-sectional view showing a step of forming a gate electrode and an interlayer insulating film.

FIG. 22 is a schematic cross-sectional view showing a configuration of the silicon carbide semiconductor device according to the present embodiment.

### DETAILED DESCRIPTION

### Problem to be Solved by the Present Disclosure

An object of the present disclosure is to provide a silicon carbide substrate, a silicon carbide epitaxial substrate, and a method of manufacturing a silicon carbide semiconductor device, which can improve the yield of the silicon carbide semiconductor device.

### Advantageous Effect of the Present Disclosure

According to the present disclosure, there can be provided a silicon carbide substrate, a silicon carbide epitaxial substrate, and a method of manufacturing a silicon carbide semiconductor device, which can improve the yield of the silicon carbide semiconductor device.

### Description of Embodiments

First, embodiments of the present disclosure are described one by one.

(1) A silicon carbide substrate 100 according to the present disclosure has a first main surface 1 and a second main surface 2 opposite to first main surface 1. One or more first voids 10 are present in first main surface 1. An area density of first voids 10 is less than 0.9/cm². When viewed in a direction perpendicular to first main surface 1, first void 10 has a width of 10 μm or more and 100 μm or less. When viewed in a direction parallel to first main surface 1, the width of first void 10 increases from first main surface 1 toward second main surface 2. When viewed in the direction parallel to first main surface 1, first void 10 has a depth smaller than a thickness of silicon carbide substrate 100. First main surface 1 is a carbon plane, or a plane inclined at an off angle θ of 8° or less relative to the carbon plane.

(2) A silicon carbide substrate 100 according to the present disclosure has a first main surface 1 and a second main surface 2 opposite to first main surface 1. One or more first voids 10 are present in first main surface 1, and one or more second voids 20 are present in second main surface 2. An area density of second voids 20 is less than 0.9/cm². When viewed in a direction perpendicular to first main surface 1, each of first void 10 and second void 20 has a width of 10 μm or more and 100 μm or less. When viewed in a direction parallel to first main surface 1, the width of each of first void 10 and second void 20 increases from first main surface 1 toward second main surface 2. When viewed in the direction parallel to first main surface 1, each of first void 10 and second void 20 has a depth smaller than a thickness of silicon carbide substrate 100. Second main surface 2 is a silicon plane, or a plane inclined at an off angle θ of 8° or less relative to the silicon plane.

(3) In silicon carbide substrate 100 according to (1) or (2), when first main surface 1 is divided into a plurality of square regions 30, each of which is 5 mm on a side, the plurality of square regions 30 may be formed by a first region 31 where an area density of threading screw dislocations 4 is 3000/cm² or more, a second region 32 where the area density of threading screw dislocations 4 is 1000/cm² or more and less than 3000/cm², and a third region 33 where the area density of threading screw dislocations 4 is less than 1000/cm². A ratio of an area of first region 31 to a total area of first region 31, second region 32 and third region 33 may be 1% or more and 10% or less.

(4) In silicon carbide substrate 100 according to (3), the ratio of the area of first region 31 to the total area of first region 31, second region 32 and third region 33 may be 5% or more.

(5) In silicon carbide substrate 100 according to any one of (1) to (4), an area density of threading screw dislocations 4 in second main surface 2 may be 1500/cm² or less.

(6) In silicon carbide substrate 100 according to any one of (1) to (5), ten or more and twenty or less first carbon inclusions 71 may be present in a first cuboid region 61 of silicon carbide substrate 100. In the direction perpendicular to first main surface 1, a distance from first main surface 1 to an upper end surface of first cuboid region 61 may be 50 μm, and a distance from first main surface 1 to a lower end surface of first cuboid region 61 may be 200 μm. When viewed in the direction perpendicular to first main surface 1, a long side of first cuboid region 61 may have a length of 0.82 mm, and a short side of first cuboid region 61 may have a length of 0.7 mm. When viewed in the direction perpendicular to first main surface 1, first void 10 may overlap first cuboid region 61. When viewed in the direction perpendicular to first main surface 1, each of first carbon inclusions 71 may have a maximum length of 5 μm or more and 50 μm or less.

(7) In silicon carbide substrate 100 according to any one of (1) to (6), three or more and less than ten second carbon inclusions 72 may be present in a second cuboid region 62 of silicon carbide substrate 100. In the direction perpendicular to first main surface 1, a distance from first main surface 1 to an upper end surface of second cuboid region 62 may be 50 μm, and a distance from first main surface 1 to a lower end surface of second cuboid region 62 may be 200 μm. When viewed in the direction perpendicular to first main surface 1, a long side of second cuboid region 62 may have a length of 0.82 mm, and a short side of second cuboid region 62 may have a length of 0.7 mm. When viewed in the direction perpendicular to first main surface 1, an area density of threading screw dislocations 4 in a region of first main surface 1 that overlaps second cuboid region 62 may be 3000/cm² or more. When viewed in the direction perpendicular to first main surface 1, each of second carbon inclusions 72 may have a maximum length of 5 μm or more and 50 μm or less.

(8) In silicon carbide substrate 100 according to any one of (1) to (7), first main surface 1 may have a diameter of 150 mm or more.

(9) In silicon carbide substrate 100 according to any one of (1) to (8), first main surface 1 may be a plane inclined at an off angle θ of 1° or more and 4° or less relative to the carbon plane.

(10) A silicon carbide epitaxial substrate 200 according to the present disclosure includes silicon carbide substrate 100 according to any one of (1) to (9), and a silicon carbide epitaxial layer 60 provided on silicon carbide substrate 100.

(11) A method of manufacturing a silicon carbide semiconductor device 400 according to the present disclosure includes steps described below. Silicon carbide epitaxial substrate 200 according to (10) is prepared. Silicon carbide epitaxial substrate 200 is processed.

### Details of Embodiments of the Present Disclosure

Hereinafter, embodiments of the present disclosure will be described in detail based on the drawings. It should be noted that the same or corresponding parts in the drawings below are denoted by the same reference numbers and description thereof will not be repeated. Regarding crystallographic indications in the present specification, an individual orientation is represented by [ ], a group orientation is represented by < >, an individual plane is represented by ( ) and a group plane is represented by { }. In addition, a negative index is supposed to be crystallographically indicated by putting “-” (bar) above a numeral, but is indicated by putting the negative sign before the numeral in the present specification.

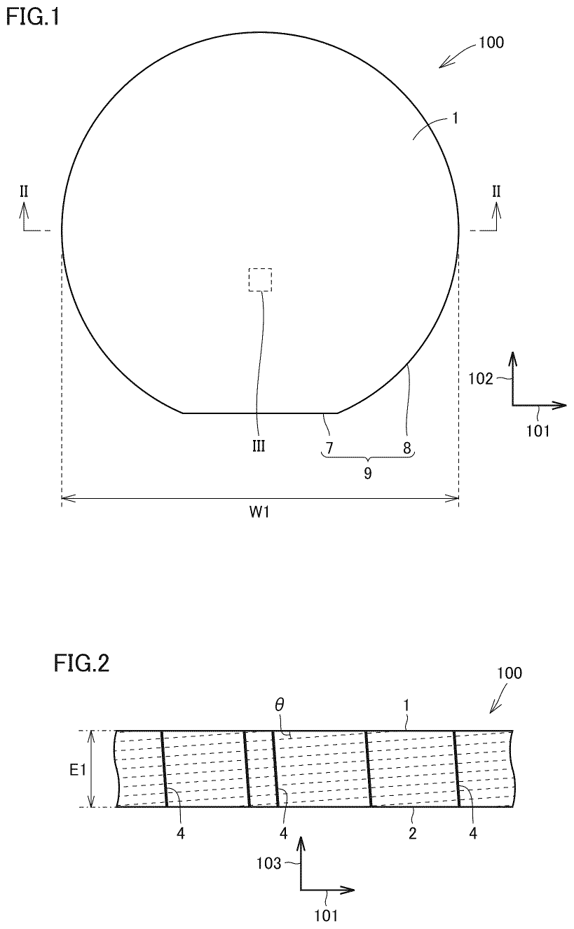

First, a configuration of a silicon carbide substrate 100 according to the present embodiment is described. FIG. 1 is a schematic plan view showing the configuration of silicon carbide substrate 100 according to the present embodiment.

As shown in FIG. 1, silicon carbide substrate 100 according to the present embodiment has a first main surface 1 and an outer circumferential side surface 9. First main surface 1 extends along each of a first direction 101 and a second direction 102. First direction 101 is not particularly limited, and is a <11-20> direction, for example. Second direction 102 is not particularly limited, and is a <1-100> direction, for example. An off direction is first direction 101, for example. Silicon carbide substrate 100 is made of hexagonal silicon carbide, for example. The hexagonal silicon carbide has a 4H polytype, for example. Silicon carbide substrate 100 includes an n type impurity such as nitrogen.

First main surface 1 is a carbon plane, or a plane inclined in the off direction relative to the carbon plane. Stated another way, first main surface 1 is a (000-1) plane, or a plane inclined in the off direction relative to the (000-1) plane. Similarly, a second main surface 2 (see FIG. 2) is a silicon plane, or a plane inclined in the off direction relative to the silicon plane. Stated another way, second main surface 2 is a (0001) plane, or a plane inclined in the off direction relative to the (0001) plane.

As shown in FIG. 1, outer circumferential side surface 9 has an orientation flat portion 7 and an arc-shaped portion 8. Arc-shaped portion 8 is contiguous to orientation flat portion 7. As shown in FIG. 1, when viewed in a direction perpendicular to first main surface 1, orientation flat portion 7 extends along first direction 101.

First main surface 1 has a diameter W1 of 150 mm, for example. Diameter W1 may be 150 mm or more, or 200 mm or more. The upper limit to diameter W1 is not particularly limited, and may be 300 mm or less, for example. When viewed in the direction perpendicular to first main surface 1, diameter W1 refers to the longest linear distance between two different points on outer circumferential side surface 9.

FIG. 2 is a schematic cross-sectional view along a line II-II shown in FIG. 1. The cross section shown in FIG. 2 is perpendicular to first main surface 1, and is parallel to first direction 101. As shown in FIG. 2, silicon carbide substrate 100 according to the present embodiment has second main surface 2. Second main surface 2 is opposite to first main surface 1. Silicon carbide substrate 100 has a thickness E1 of 300 μm or more and 700 μm or less, for example. A third direction 103 is a direction perpendicular to each of first direction 101 and second direction 102. A thickness direction of silicon carbide substrate 100 is the same as third direction 103.

When first main surface 1 is inclined in the off direction relative to the carbon plane, the plane inclined in the off direction relative to the carbon plane may have an off angle θ of 8° or less. The upper limit to off angle θ is not particularly limited, and may be 6° or less, or 4° or less, for example. The lower limit to off angle θ is not particularly limited, and may be 1° or more, or 2° or more, for example. The off direction of the plane inclined relative to the carbon plane is not particularly limited, and is the <11-20> direction, for example.

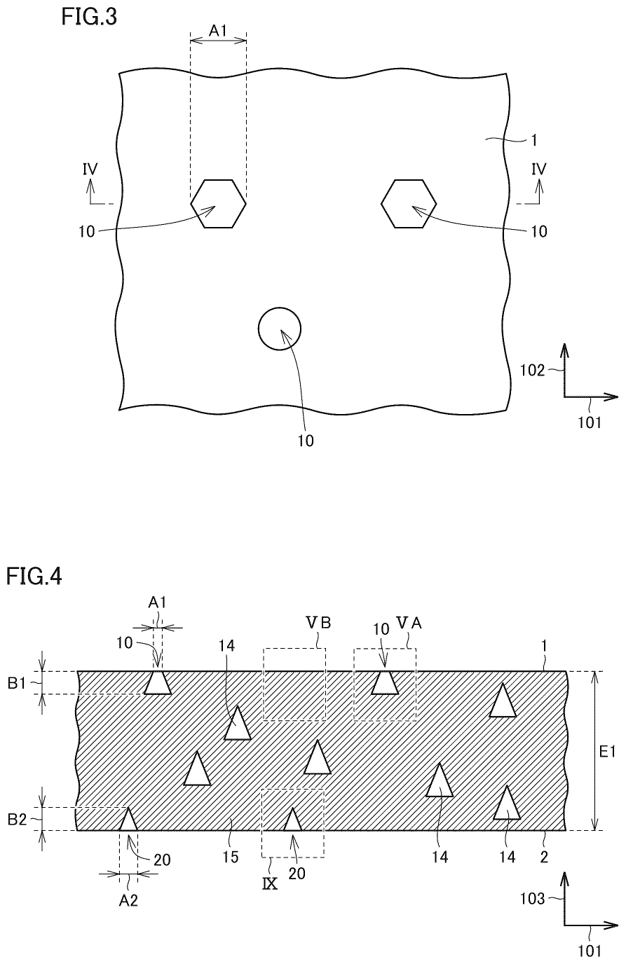

FIG. 3 is an enlarged plan view of a region III shown in FIG. 1. As shown in FIG. 3, one or more first voids 10 are present in first main surface 1. When viewed in the direction perpendicular to first main surface 1, an opening of first void 10 has a hexagonal shape, for example. The shape of the opening of first void 10 is not particularly limited, and may be circular, elliptical, or polygonal other than hexagonal, for example.

When viewed in the direction perpendicular to first main surface 1, first void 10 has a width (first width A1) of 10 μm or more and 100 μm or less. The width of first void 10 refers to the maximum value of the width between any two points at the opening of first void 10. The width of first void 10 may be a width along the off direction, for example. The lower limit value of first width A1 is not particularly limited, and may be 20 μm or more, or 30 μm or more, for example. The upper limit value of first width A1 is not particularly limited, and may be 80 μm or less, or 60 μm or less, for example.

In first main surface 1, the area density of first voids 10 is less than 0.9/cm². The upper limit to the area density of first voids 10 is not particularly limited, and may be 0.6/cm² or less, or 0.4/cm² or less, for example. The lower limit to the area density of first voids 10 is not particularly limited, and may be 0.02/cm² or more, 0.05/cm² or more, or 0.15/cm² or more, for example.

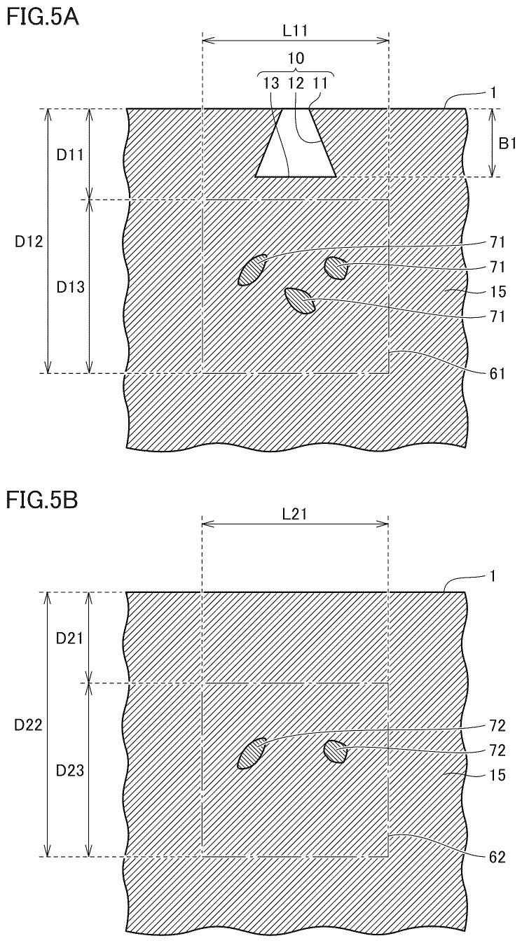

FIG. 4 is a schematic cross-sectional view along a line IV-IV shown in FIG. 3. The cross section shown in FIG. 4 is perpendicular to first main surface 1, and is parallel to first direction 101. As shown in FIG. 4, when viewed in a direction parallel to first main surface 1, the width of first void 10 increases from first main surface 1 toward second main surface 2.

FIG. 5A is an enlarged schematic cross-sectional view of a region VA shown in FIG. 4. As shown in FIG. 5A, first void 10 has a first opening 11, a first side surface portion 12, and a first bottom portion 13. First opening 11 is located at first main surface 1. First bottom portion 13 is located between first main surface 1 and second main surface 2. First side surface portion 12 is located between first opening 11 and first bottom portion 13. First side surface portion 12 is contiguous to each of first opening 11 and first bottom portion 13. When viewed in the direction parallel to first main surface 1, first side surface portion 12 may be linear.

As shown in FIGS. 4 and 5A, when viewed in the direction parallel to first main surface 1, first void 10 has a trapezoidal shape, for example. The upper base of the trapezoid is located at first opening 11. The lower base of the trapezoid is located at first bottom portion 13. When viewed in the direction parallel to first main surface 1, first bottom portion 13 has a greater width than first opening 11.

When viewed in the direction parallel to first main surface 1, first void 10 has a depth (first depth B1) smaller than the thickness of silicon carbide substrate 100. Stated another way, first void 10 does not extend through silicon carbide substrate 100. First void 10 is exposed only at first main surface 1, and is not exposed at second main surface 2.

First depth B1 may be greater than or equal to the width (first width A1) of first void 10 at first main surface 1. Stated another way, first depth B1 may be the same as first width A1, or may be larger than first width A1. The upper limit to first depth B1 is not particularly limited, and may be less than or equal to five times, or less than or equal to three times, the width of first bottom portion 13 of first void 10, for example.

As shown in FIG. 5A, carbon inclusions (first carbon inclusions 71) are present below first void 10. First carbon inclusions 71 may face first bottom portion 13 of first void 10. First carbon inclusions 71 are embedded in a silicon carbide region 15 of silicon carbide substrate 100. In the thickness direction of silicon carbide substrate 100, a distance between first main surface 1 and each of first carbon inclusions 71 is 50 μm or more and 200 μm or less, for example. Stated from a different perspective, first carbon inclusions 71 are present in a first cuboid region 61 located at a distance of 50 μm or more and 200 μm or less from first main surface 1 toward second main surface 2.

In the direction perpendicular to first main surface 1, a distance (first distance D11) from first main surface 1 to an upper end surface of first cuboid region 61 is 50 μm. In the direction perpendicular to first main surface 1, a distance (second distance D12) from first main surface 1 to a lower end surface of first cuboid region 61 is 200 μm. In the direction perpendicular to first main surface 1, a distance (third distance D13) from the lower end surface to the upper end surface of first cuboid region 61 is 150 μm.

FIG. 5B is an enlarged schematic cross-sectional view of a region VB shown in FIG. 4. In the direction perpendicular to first main surface 1, a distance (first distance D21) from first main surface 1 to an upper end surface of a second cuboid region 62 is 50 μm. In the direction perpendicular to first main surface 1, a distance (second distance D22) from first main surface 1 to a lower end surface of second cuboid region 62 is 200 μm. In the direction perpendicular to first main surface 1, a distance (third distance D23) from the lower end surface to the upper end surface of second cuboid region 62 is 150 μm.

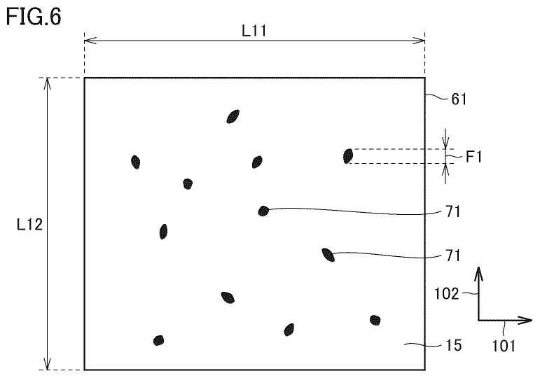

FIG. 6 is a perspective plan view showing a configuration of first cuboid region 61. As shown in FIG. 6, when viewed in the direction perpendicular to first main surface 1, first cuboid region 61 has a rectangular shape. The long side of first cuboid region 61 has a length (first length L11) of 0.82 mm. The long side of first cuboid region 61 is parallel to first direction 101. The short side of first cuboid region 61 has a length (second length L12) of 0.7 mm. The short side of first cuboid region 61 is parallel to second direction 102.

When viewed in the direction perpendicular to first main surface 1, first void 10 overlaps first cuboid region 61. When viewed in the direction perpendicular to first main surface 1, first cuboid region 61 is determined such that the center of first void 10 coincides with the center of first cuboid region 61. When viewed in the direction perpendicular to first main surface 1, each of first carbon inclusions 71 has a maximum length F1 of 5 μm or more and 50 μm or less.

FIG. 6 shows first carbon inclusions 71 present in first cuboid region 61. As shown in FIG. 6, ten or more and twenty or less first carbon inclusions 71 may be present in first cuboid region 61. The lower limit to the number of first carbon inclusions 71 present in first cuboid region 61 is not particularly limited, and may be eleven or more, or twelve or more, for example. The upper limit to the number of first carbon inclusions 71 present in first cuboid region 61 is not particularly limited, and may be nineteen or less, or eighteen or less, for example.

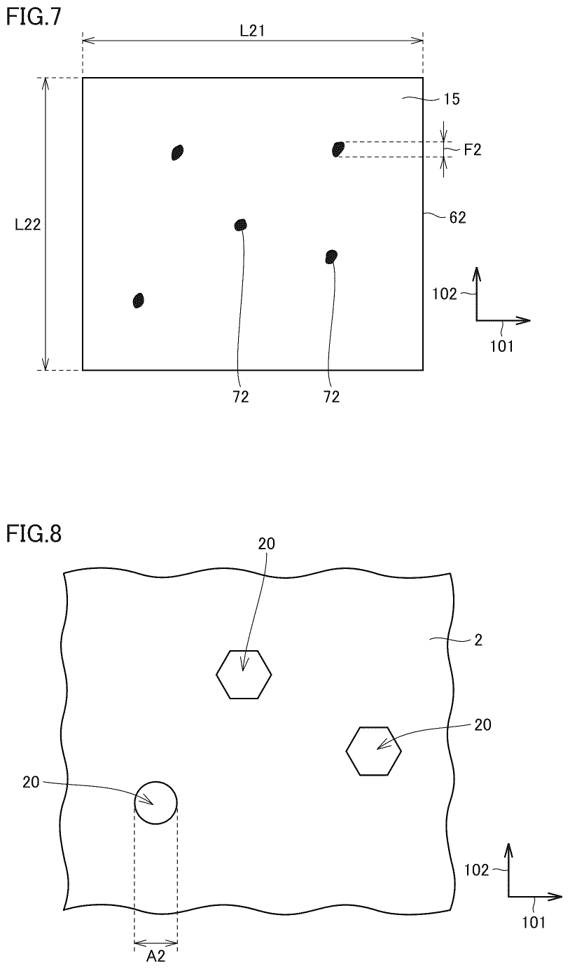

FIG. 7 is a perspective plan view showing a configuration of second cuboid region 62. As shown in FIG. 7, when viewed in the direction perpendicular to first main surface 1, second cuboid region 62 has a rectangular shape. The long side of second cuboid region 62 has a length (first length L21) of 0.82 mm. The long side of second cuboid region 62 is parallel to first direction 101. The short side of second cuboid region 62 has a length (second length L22) of 0.7 mm. The short side of second cuboid region 62 is parallel to second direction 102.

Second cuboid region 62 is a region located at a distance of 50 μm or more and 200 μm or less from first main surface 1 toward second main surface 2. A region where threading screw dislocations 4 are concentrated is present above second cuboid region 62. Specifically, when viewed in the direction perpendicular to first main surface 1, the area density of threading screw dislocations 4 in a region of first main surface 1 that overlaps second cuboid region 62 is 3000/cm² or more. When viewed in the direction perpendicular to first main surface 1, second cuboid region 62 is determined such that the center of the region of first main surface 1 that overlaps second cuboid region 62 coincides with the center of a first region 31 which will be described later. Second cuboid region 62 includes second carbon inclusions 72. Second carbon inclusions 72 are embedded in silicon carbide region 15 of silicon carbide substrate 100. When viewed in the direction perpendicular to first main surface 1, each of second carbon inclusions 72 has a maximum length F2 of 5 μm or more and 50 μm or less.

FIG. 7 shows second carbon inclusions 72 present in second cuboid region 62. As shown in FIG. 7, three or more and less than ten second carbon inclusions 72 are present in second cuboid region 62. The lower limit to the number of second carbon inclusions 72 present in second cuboid region 62 is not particularly limited, and may be four or more, or five or more, for example. The upper limit to the number of second carbon inclusions 72 present in second cuboid region 62 is not particularly limited, and may be less than nine, or less than eight, for example.

FIG. 8 is an enlarged schematic plan view of second main surface 2. As shown in FIG. 8, one or more second voids 20 are present in second main surface 2. When viewed in a direction perpendicular to second main surface 2, an opening of second void 20 has a hexagonal shape, for example. The shape of the opening of second void 20 is not particularly limited, and may be circular, elliptical, or polygonal other than hexagonal, for example.

When viewed in the direction perpendicular to second main surface 2, second void 20 has a width (second width A2) of 10 μm or more and 100 μm or less. The width of second void 20 refers to the maximum value of the width between any two points at the opening of second void 20. The width of second void 20 may be a width along the off direction, for example. The lower limit value of second width A2 is not particularly limited, and may be 20 μm or more, or 30 μm or more, for example. The upper limit value of second width A2 is not particularly limited, and may be 80 μm or less, or 60 μm or less, for example.

In second main surface 2, the area density of second voids 20 is less than 0.9/cm². The upper limit to the area density of second voids 20 is not particularly limited, and may be 0.6/cm² or less, or 0.4/cm² or less, for example. The lower limit to the area density of second voids 20 is not particularly limited, and may be 0.02/cm² or more, 0.05/cm² or more, or 0.15/cm² or more, for example.

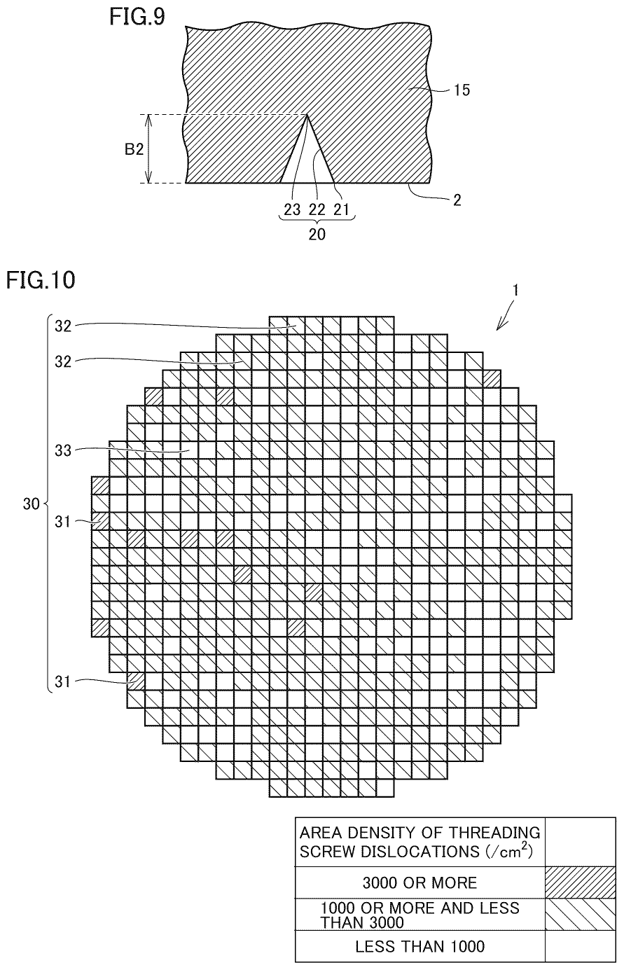

FIG. 9 is an enlarged schematic cross-sectional view of a region IX shown in FIG. 4. As shown in FIG. 9, when viewed in the direction parallel to first main surface 1, the width of second void 20 increases from first main surface 1 toward second main surface 2. Second void 20 has a second opening 21, a second side surface portion 22, and a second bottom portion 23. Second opening 21 is located at second main surface 2. Second bottom portion 23 is located between first main surface 1 and second main surface 2. Second side surface portion 22 is located between second opening 21 and second bottom portion 23. Second side surface portion 22 is contiguous to each of second opening 21 and second bottom portion 23. When viewed in a direction parallel to second main surface 2, second side surface portion 22 may be linear.

As shown in FIGS. 4 and 9, when viewed in the direction parallel to first main surface 1, second void 20 has a triangular shape, for example. The base of the triangle is located at second opening 21. The apex of the triangle is located at second bottom portion 23.

When viewed in the direction parallel to first main surface 1, second void 20 has a depth (second depth B2) smaller than the thickness of silicon carbide substrate 100. Stated another way, second void 20 does not extend through silicon carbide substrate 100. Second void 20 is exposed only at second main surface 2, and is not exposed at first main surface 1.

Second depth B2 may be greater than or equal to the width (second width A2) of second void 20 at second main surface 2. Stated another way, second depth B2 may be the same as second width A2, or may be larger than second width A2. The upper limit to second depth B2 is not particularly limited, and may be less than or equal to five times, or less than or equal to three times, the width of second opening 21 of second void 20, for example.

As shown in FIG. 4, third voids 14 are formed in silicon carbide substrate 100. Third voids 14 are located inside silicon carbide substrate 100. Third voids 14 are confined in silicon carbide substrate 100. Stated from a different perspective, third voids 14 are not exposed at either first main surface 1 or second main surface 2. When viewed in the direction parallel to first main surface 1, each of third voids 14 has a width that increases from first main surface 1 toward second main surface 2. When viewed in the direction parallel to first main surface 1, each of third voids 14 has a triangular shape, for example.

Next, a method of measuring the area density of each of the first voids and the second voids is described.

Each of first voids 10 and second voids 20 is identified using an optical microscope. A bottomed hole which opens to first main surface 1, has a width of 10 μm or more and 100 μm or less when viewed in the direction perpendicular to first main surface 1, and increases in width from first main surface 1 toward second main surface 2 is identified as first void 10. A value determined by dividing the number of first voids 10 in a measurement region of first main surface 1 by the area of the measurement region of first main surface 1 is defined as the area density of first voids 10. A region of first main surface 1 that is within 5 mm from outer circumferential side surface 9 is excluded from the measurement region.

Similarly, a bottomed hole which opens to second main surface 2, has a width of 10 μm or more and 100 μm or less when viewed in the direction perpendicular to second main surface 2, and increases in width from first main surface 1 toward second main surface 2 is identified as second void 20. A value determined by dividing the number of second voids 20 in a measurement region of second main surface 2 by the area of the measurement region of second main surface 2 is defined as the area density of second voids 20. A region of second main surface 2 that is within 5 mm from outer circumferential side surface 9 is excluded from the measurement region.

FIG. 10 is a schematic plan view showing the measurement region of first main surface 1, excluding the region within 5 mm from outer circumferential side surface 9, that has been divided into a plurality of square regions 30. Each the plurality of square regions 30 has a side length of 5 mm. A first side of each of the plurality of square regions 30 is parallel to first direction 101. A second side of each of the plurality of square regions 30 is parallel to second direction 102. The second side is contiguous to the first side.

As shown in FIG. 10, from the lower side to the upper side of first main surface 1 along second direction 102, the number of the plurality of square regions 30 is, for example, 7, 13, 17, 19, 21, 23, 23, 25, 25, 26, 27, 27, 27, 27, 27, 27, 27, 26, 25, 25, 23, 23, 21, 19, 17, 13, and 7.

As shown in FIG. 10, the plurality of square regions 30 are formed by first regions 31, second regions 32, and third regions 33. Each of first regions 31 is a region where the area density of threading screw dislocations 4 is 3000/cm² or more. Each of second regions 32 is a region where the area density of threading screw dislocations 4 is 1000/cm² or more and less than 3000/cm². Each of third regions 33 is a region where the area density of threading screw dislocations 4 is less than 1000/cm².

The ratio of the area of first regions 31 to the total area of first regions 31, second regions 32 and third regions 33 may be 1% or more and 10% or less, for example. The lower limit to the ratio of the area of first regions 31 to the total area of first regions 31, second regions 32 and third regions 33 is not particularly limited, and may be 3% or more, or 5% or more, for example. The upper limit to the ratio of the area of first regions 31 to the total area of first regions 31, second regions 32 and third regions 33 is not particularly limited, and may be 9% or less, or 8% or less, for example.

The area density of threading screw dislocations 4 in second main surface 2 is 1500/cm² or less, for example. The upper limit to the area density of threading screw dislocations 4 in second main surface 2 is not particularly limited, and may be 1400/cm² or less, or 1300/cm² or less, for example. The lower limit to the area density of threading screw dislocations 4 in second main surface 2 is not particularly limited, and may be 500/cm² or more, or 900/cm² or more, for example.

Next, a method of measuring the area density of the threading screw dislocations is described.

The area density of threading screw dislocations 4 is measured using molten potassium hydroxide (KOH), for example. Specifically, the silicon carbide region near threading screw dislocations 4 exposed at second main surface 2 is etched by molten KOH, to thereby form etch pits in second main surface 2. Each observed region for etch pits is 0.82 mm×0.70 mm, for example. Observed regions are provided at regular intervals in each of first direction 101 and second direction 102.

The observed regions have a pitch of 5 mm. At least one of sodium peroxide (Na₂O₂), barium peroxide (BaO₂) and sodium nitrate (NaNO₃) may be added to the molten KOH.

The number of the etch pits caused by threading screw dislocations 4 is measured in all observed regions. A value determined by dividing the total number of the etch pits in all observed regions by the total area of the observed regions corresponds to the area density of threading screw dislocations 4 in second main surface 2. The temperature of the KOH melt is about 500° C. or more and 550° C. or less, for example. The etching time is about 5 minutes or more and 10 minutes or less. After the etching, the observed regions of second main surface 2 are observed using a Nomarski differential interference microscope.

Next, a configuration of an apparatus for manufacturing a silicon carbide crystal according to the present embodiment is described.

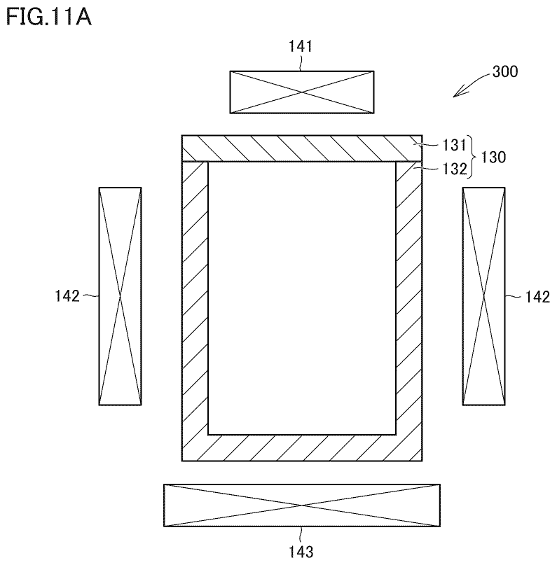

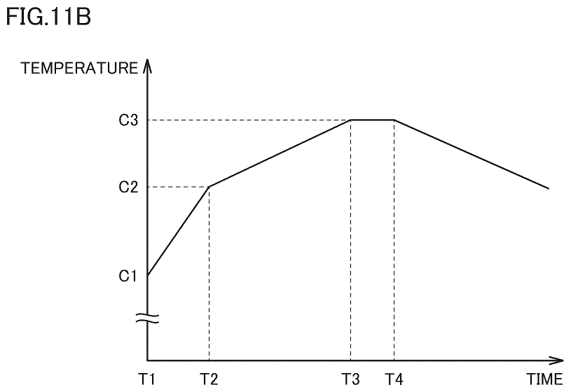

FIG. 11A is a schematic partial cross-sectional view showing the configuration of the apparatus for manufacturing a silicon carbide crystal according to the present embodiment. As shown in FIG. 11A, an apparatus 300 for manufacturing a silicon carbide crystal mainly includes a crucible 130, a first resistive heater 141, a second resistive heater 142, and a third resistive heater 143. Crucible 130 is made of graphite. Crucible 130 includes a source material housing portion 132 and a lid portion 131. Lid portion 131 is disposed on source material housing portion 132. A graphite member (not shown) is placed in crucible 130.

First resistive heater 141 is disposed above lid portion 131. Second resistive heater 142 is disposed to surround the outer circumference of source material housing portion 132. Third resistive heater 143 is disposed below a bottom surface of source material housing portion 132. Crucible 130 is heated by application of electric power to first resistive heater 141, second resistive heater 142, and third resistive heater 143.

Next, a method of manufacturing silicon carbide substrate 100 according to the present embodiment is described. First, a step of firing the crucible and the graphite member placed in the crucible is performed. Specifically, the crucible and the graphite member placed in the crucible are heated at a temperature of 3000° C. in an argon gas atmosphere. The heating time for the crucible is 10 hours, for example. The argon gas has a pressure of 10 kPa, for example.

FIG. 11B is a schematic diagram showing a relation between temperature and time in the step of firing the crucible and the graphite member placed in the crucible.

In FIG. 11B, the vertical axis represents temperature, and the horizontal axis represents time. As shown in FIG. 11B, in a first temperature increasing step, the temperature of crucible 130 increases from a first temperature C1 to a second temperature C2 in a period from a first time point T1 to a second time point T2. First temperature C1 is 1100° C., for example. Second temperature C2 is 2200° C., for example.

Next, in a second temperature increasing step, the temperature of crucible 130 increases from second temperature C2 to a third temperature C3 in a period from second time point T2 to a third time point T3. Third temperature C3 is the maximum attained temperature. Third temperature C3 is 3000° C., for example. The rate of temperature increase in the first temperature increasing step is 100° C./hour, for example. The rate of temperature increase in the second temperature increasing step is 20° C./hour or less. The rate of temperature increase in the second temperature increasing step is lower than the rate of temperature increase in the first temperature increasing step.

Next, a firing step is performed. The temperature of crucible 130 is held at third temperature C3 in a period from third time point T3 to a fourth time point T4. The time from third time point T3 to fourth time point T4 is a firing time. Next, a cooling step is performed. Crucible 130 is cooled from fourth time point T4. To prevent cracking of the member, crucible 130 is slowly cooled until the temperature of crucible 130 reaches first temperature C1. The rate of cooling of crucible 130 is 20° C./hour or less.

In the first temperature increasing step, the second temperature increasing step, the firing step and the cooling step, the pressure of the atmospheric gas in crucible 130 is maintained at about 10 kPa, for example. The atmospheric gas includes an inert gas such as argon gas or helium gas.

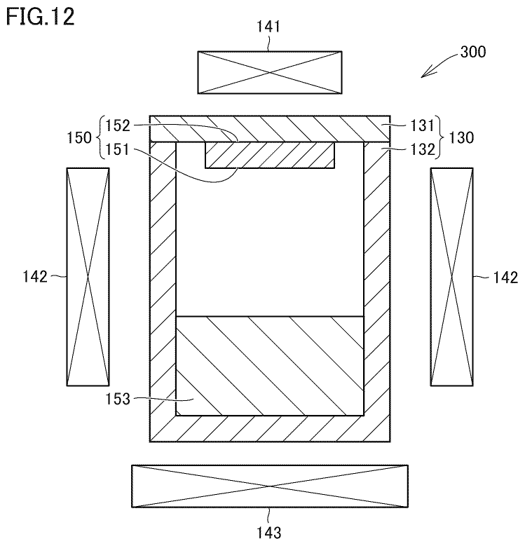

FIG. 12 is a schematic cross-sectional view showing a step of placing a silicon carbide source material and a seed substrate in the crucible. As shown in FIG. 12, a silicon carbide source material 153 is placed in source material housing portion 132. Silicon carbide source material 153 is a powder of polycrystalline silicon carbide, for example. A seed substrate 150 is fixed to lid portion 131 with an adhesive (not shown), for example. Seed substrate 150 has a growth surface 151 and an attachment surface 152. Attachment surface 152 is opposite to growth surface 151. Growth surface 151 faces silicon carbide source material 153. Attachment surface 152 faces lid portion 131. Growth surface 151 of seed substrate 150 is disposed to face the surface of silicon carbide source material 153.

Seed substrate 150 is a silicon carbide single-crystal substrate having a 4H polytype, for example. Growth surface 151 has a diameter of 150 mm, for example. Growth surface 151 may have a diameter of 150 mm or more. Growth surface 151 is a carbon plane, or a plane inclined at an off angle of about 8° or less relative to the carbon plane. Seed substrate 150 and silicon carbide source material 153 are prepared as described above.

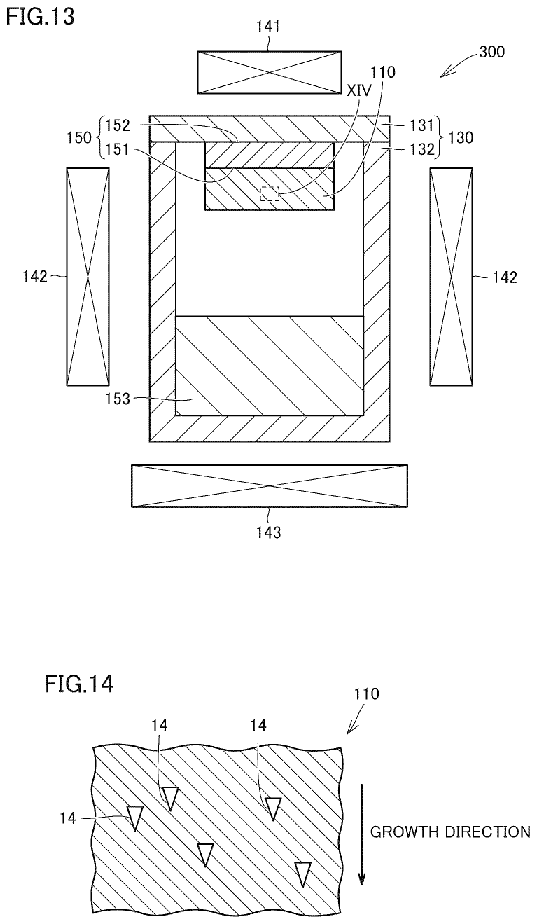

FIG. 13 is a schematic cross-sectional view showing a step of growing a silicon carbide crystal. First, the pressure in crucible 130 is reduced while the temperature of growth surface 151 of seed substrate 150 is lower than the temperature of silicon carbide source material 153. The pressure of the atmospheric gas in crucible 130 is reduced to 1.0 kPa, for example. Accordingly, silicon carbide source material 153 starts to be sublimated, and the sublimated silicon carbide gas is recrystallized on growth surface 151 of seed substrate 150. A silicon carbide crystal 110 starts to grow as a single crystal on growth surface 151 of seed substrate 150. During the growth of silicon carbide crystal 110, the pressure in crucible 130 is maintained at about 0.1 kPa or more and 3 kPa or less, for example.

As described above, silicon carbide crystal 110 is grown on seed substrate 150 by the sublimation of silicon carbide source material 153. In the step of growing silicon carbide crystal 110, the temperature of silicon carbide crystal 110 is 2100° C. or more and 2300° C. or less, for example. The lower limit to the temperature of silicon carbide crystal 110 is not particularly limited, and may be 2125° C. or more, or 2150° C. or more, for example. The upper limit to the temperature of silicon carbide crystal 110 is not particularly limited, and may be 2250° C. or less, or 2275° C. or less, for example.

FIG. 14 is an enlarged schematic diagram showing a configuration of a region XIV shown in FIG. 13. As shown in FIG. 14, the plurality of third voids 14 are formed in silicon carbide crystal 110. In a cross section parallel to the growth direction of silicon carbide crystal 110, each of the plurality of third voids 14 has a triangular shape, for example. The width of third void 14 in a direction perpendicular to the growth direction of silicon carbide crystal 110 decreases along the growth direction of silicon carbide crystal 110. Stated from a different perspective, the width of third void 14 in the direction perpendicular to the growth direction of silicon carbide crystal 110 decreases from seed substrate 150 toward silicon carbide source material 153.

Next, silicon carbide crystal 110 is sliced. Specifically, silicon carbide crystal 110 is sliced using a saw wire, for example, along a plane perpendicular to the central axis of silicon carbide crystal 110. Accordingly, a plurality of silicon carbide substrates 100 are obtained (see FIG. 4). As shown in FIG. 4, each of silicon carbide substrates 100 has first main surface 1 and second main surface 2. Of the plurality of third voids 14, those exposed at first main surface 1 are first voids 10. Of the plurality of third voids 14, those exposed at second main surface 2 are second voids 20.

### <Method of Manufacturing Silicon Carbide Semiconductor Device>

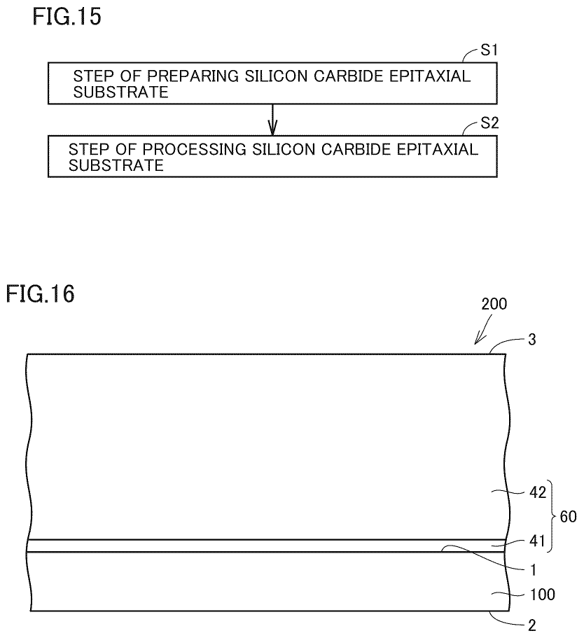

Next, a method of manufacturing a silicon carbide semiconductor device 400 according to the present embodiment is described. FIG. 15 is a flowchart schematically showing the method of manufacturing silicon carbide semiconductor device 400 according to the present embodiment. As shown in FIG. 15, the method of manufacturing silicon carbide semiconductor device 400 according to the present embodiment mainly includes a step of preparing a silicon carbide epitaxial substrate 200 (S1) and a step of processing silicon carbide epitaxial substrate 200 (S2).

First, the step of preparing silicon carbide epitaxial substrate 200 (S1) is performed. In the step of preparing silicon carbide epitaxial substrate 200 (S1), silicon carbide substrate 100 according to the present embodiment is first prepared (see FIG. 1).

Next, a silicon carbide epitaxial layer 60 is formed on silicon carbide substrate 100. Specifically, silicon carbide epitaxial layer 60 is formed on first main surface 1 of silicon carbide substrate 100 by epitaxial growth. In the epitaxial growth, silane (SiH₄) and propane (C₃H₈) are used as a source material gas, for example, and hydrogen (H₂) is used as a carrier gas. The temperature for the epitaxial growth is about 1400° C. or more and 1700° C. or less, for example. In the epitaxial growth, an n type impurity such as nitrogen is introduced into silicon carbide epitaxial layer 60. Silicon carbide epitaxial substrate 200 according to the present embodiment is prepared in this manner.

FIG. 16 is a schematic cross-sectional view showing a configuration of silicon carbide epitaxial substrate 200 according to the present embodiment. For the sake of convenience of description, each of first voids 10, second voids 20, third voids 14, first carbon inclusions 71 and second carbon inclusions 72 is not shown in FIG. 16 and subsequent figures.

As shown in FIG. 16, silicon carbide epitaxial substrate 200 includes silicon carbide substrate 100 and silicon carbide epitaxial layer 60. Silicon carbide epitaxial layer 60 is provided on silicon carbide substrate 100. Silicon carbide epitaxial layer 60 has a third main surface 3. Third main surface 3 forms a front surface of silicon carbide epitaxial substrate 200. Second main surface 2 forms a backside surface of silicon carbide epitaxial substrate 200.

Silicon carbide epitaxial layer 60 may include a buffer layer 41 and a drift layer 42. Buffer layer 41 is in contact with silicon carbide substrate 100 at first main surface 1. Drift layer 42 is provided on buffer layer 41. Each of buffer layer 41 and drift layer 42 includes an n type impurity such as nitrogen. The n type impurity included in buffer layer 41 may have a higher concentration than the n type impurity included in drift layer 42.

Next, the step of processing silicon carbide epitaxial substrate 200 (S2) is performed. Specifically, silicon carbide epitaxial substrate 200 is processed as described below. First, ion implantation is performed into silicon carbide epitaxial substrate 200.

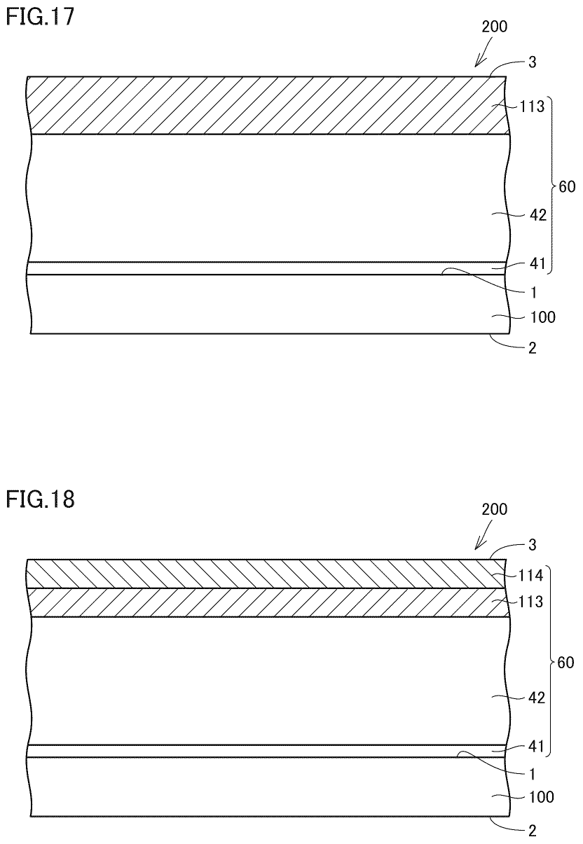

FIG. 17 is a schematic cross-sectional view showing a step of forming a body region. In the step of forming a body region, a p type impurity such as aluminum is ion-implanted into third main surface 3 of silicon carbide epitaxial layer 60. Accordingly, a body region 113 having p type conductivity is formed. A portion where body region 113 is not formed serves as drift layer 42 and buffer layer 41. Body region 113 has a thickness of 0.9 μm, for example. Silicon carbide epitaxial layer 60 includes buffer layer 41, drift layer 42, and body region 113.

Next, a step of forming a source region is performed. FIG. 18 is a schematic cross-sectional view showing the step of forming a source region. Specifically, an n type impurity such as phosphorus is ion-implanted into body region 113.

Accordingly, a source region 114 having n type conductivity is formed. Source region 114 has a thickness of 0.4 μm, for example. The n type impurity included in source region 114 has a higher concentration than the p type impurity included in body region 113.

Next, a p type impurity such as aluminum is ion-implanted into source region 114, to thereby form a contact region 118. Contact region 118 is formed to extend through source region 114 and body region 113 so as to be in contact with drift layer 42. The p type impurity included in contact region 118 has a higher concentration than the n type impurity included in source region 114.

Next, activation annealing is performed to activate the ion-implanted impurities. The temperature for the activation annealing is 1500° C. or more and 1900° C. or less, for example. The time for the activation annealing is about 30 minutes, for example. The atmosphere for the activation annealing is an argon atmosphere, for example.

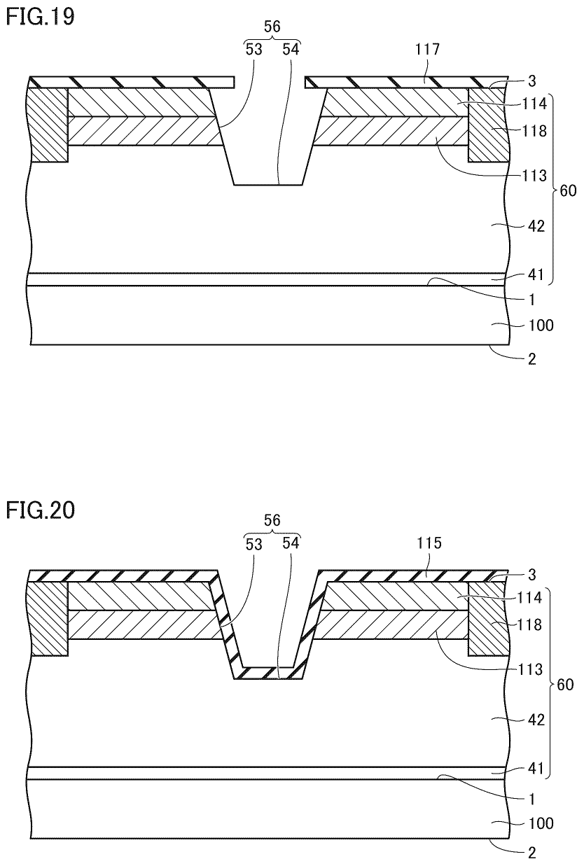

Next, a step of forming a trench in third main surface 3 of silicon carbide epitaxial layer 60 is performed. FIG. 19 is a schematic cross-sectional view showing the step of forming a trench in third main surface 3 of silicon carbide epitaxial layer 60. A mask 117 provided with an opening is formed on third main surface 3 which is formed by source region 114 and contact region 118. Mask 117 is used to remove source region 114, body region 113, and a portion of drift layer 42 by etching. As a method for the etching, inductively coupled plasma reactive ion etching can be used, for example. Specifically, inductively coupled plasma reactive ion etching using SF₆ or a mixed gas of SF₆ and O₂ as a reactive gas is used, for example. A recess is formed in third main surface 3 by the etching.

Next, thermal etching is performed in the recess. The thermal etching may be performed by heating in an atmosphere including a reactive gas having at least one type of halogen atom, for example, with mask 117 formed on third main surface 3. The at least one type of halogen atom includes at least one of chlorine (C1) atom and fluorine (F) atom. The atmosphere includes Cl₂, BCl₃, SF₆ or CF₄, for example. The thermal etching is performed using a mixed gas of chlorine gas and oxygen gas as the reactive gas, for example, at a heat treatment temperature of 700° C. or more and 1000° C. or less, for example. The reactive gas may include a carrier gas in addition to the chlorine gas and oxygen gas described above. Nitrogen gas, argon gas, helium gas or the like can be used, for example, as the carrier gas.

As shown in FIG. 19, a trench 56 is formed in third main surface 3 by the thermal etching. Trench 56 is defined by a side wall surface 53 and a bottom wall surface 54. Side wall surface 53 is formed by source region 114, body region 113, and drift layer 42. Bottom wall surface 54 is formed by drift layer 42. Mask 117 is then removed from third main surface 3.

Next, a step of forming a gate insulating film is performed. FIG. 20 is a schematic cross-sectional view showing the step of forming a gate insulating film. Specifically, silicon carbide epitaxial substrate 200 provided with trench 56 in third main surface 3 is heated at a temperature of 1300° C. or more and 1400° C. or less, for example, in an atmosphere including oxygen. Accordingly, a gate insulating film 115 is formed that is in contact with drift layer 42 at bottom wall surface 54, in contact with each of drift layer 42, body region 113 and source region 114 at side wall surface 53, and in contact with each of source region 114 and contact region 118 at third main surface 3.

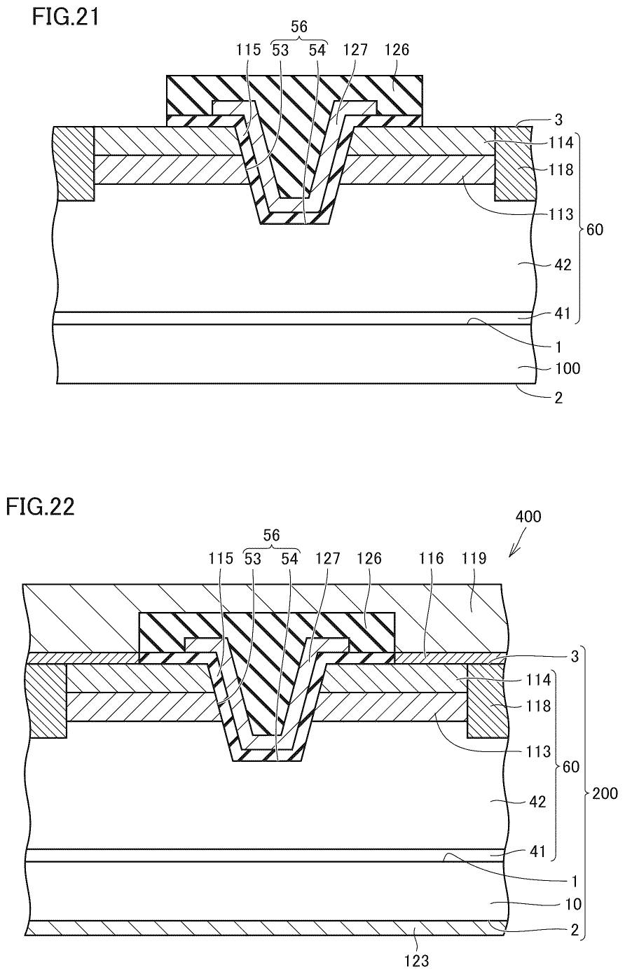

Next, a step of forming a gate electrode is performed. FIG. 21 is a schematic cross-sectional view showing the step of forming a gate electrode and an interlayer insulating film. A gate electrode 127 is formed in contact with gate insulating film 115 in trench 56. Gate electrode 127 is disposed in trench 56, and is formed on gate insulating film 115 so as to face each of side wall surface 53 and bottom wall surface 54 of trench 56. Gate electrode 127 is formed by low pressure chemical vapor deposition (LPCVD), for example.

Next, an interlayer insulating film 126 is formed. Interlayer insulating film 126 is formed to cover gate electrode 127 and to be in contact with gate insulating film 115. Interlayer insulating film 126 is formed by chemical vapor deposition, for example. Interlayer insulating film 126 is made of a material including silicon dioxide, for example. Then, interlayer insulating film 126 and gate insulating film 115 are partially etched to form an opening over source region 114 and contact region 118. Accordingly, contact region 118 and source region 114 are exposed at gate insulating film 115.

Next, a step of forming a source electrode is performed. A source electrode 116 is formed in contact with each of source region 114 and contact region 118. Source electrode 116 is formed by sputtering, for example. Source electrode 116 is made of a material including Ti (titanium), Al (aluminum) and Si (silicon), for example.

Next, alloying annealing is performed. Specifically, source electrode 116 in contact with each of source region 114 and contact region 118 is held at a temperature of 900° C. or more and 1100° C. or less for about 5 minutes, for example. Accordingly, source electrode 116 is at least partially silicided. Accordingly, source electrode 116 in ohmic contact with source region 114 is formed. Source electrode 116 may be in ohmic contact with contact region 118.

Next, a source interconnection 119 is formed. Source interconnection 119 is electrically connected to source electrode 116. Source interconnection 119 is formed to cover source electrode 116 and interlayer insulating film 126.

Next, a step of forming a drain electrode is performed. First, silicon carbide substrate 100 is polished at second main surface 2. Accordingly, silicon carbide substrate 100 has a reduced thickness. Then, a drain electrode 123 is formed. Drain electrode 123 is formed in contact with second main surface 2. Silicon carbide semiconductor device 400 according to the present embodiment is manufactured in this manner.

FIG. 22 is a schematic cross-sectional view showing a configuration of silicon carbide semiconductor device 400 according to the present embodiment. Silicon carbide semiconductor device 400 is a metal oxide semiconductor field effect transistor (MOSFET), for example. Silicon carbide semiconductor device 400 mainly includes silicon carbide epitaxial substrate 200, gate electrode 127, gate insulating film 115, source electrode 116, drain electrode 123, source interconnection 119, and interlayer insulating film 126. Silicon carbide epitaxial substrate 200 includes buffer layer 41, drift layer 42, body region 113, source region 114, and contact region 118. Silicon carbide semiconductor device 400 may be an insulated gate bipolar transistor (IGBT), for example.

Next, functions and effects of silicon carbide substrate 100, silicon carbide epitaxial substrate 200, and the method of manufacturing silicon carbide semiconductor device 400 according to the present embodiment are described.

In recent years, new defects (referred to as voids hereinafter) have been found to be present in a silicon carbide crystal. Unlike a micropipe, a void does not extend through a silicon carbide crystal. A void typically has a greater width than a micropipe. Further, a void characteristically has a width that decreases in the growth direction. If silicon carbide semiconductor device 400 is manufactured using silicon carbide substrate 100 provided with voids exposed at the main surface, silicon carbide semiconductor device 400 may have reduced reliability. As a result, silicon carbide semiconductor device 400 may have a reduced yield.

As a result of conducting detailed analysis, the inventors made the following findings and arrived at the embodiment according to the present disclosure. First, a bulk of carbon was found in a region located at a distance of from about 50 μm to about 200 μm in the growth direction from the positions of voids. Further analysis showed that the generation of the voids had been caused by a region where carbon inclusions of a certain size were densely located.

As a result of conducting further detailed analysis as to why the carbon inclusions of a certain size were densely incorporated in silicon carbide substrate 100, it was found that during the growth of a silicon carbide crystal using a crucible made of graphite, a bulk of carbon generated from the crucible and a graphite member placed in the crucible was incorporated into the silicon carbide crystal. The inventors then found that, by firing the crucible made of graphite and the graphite member placed in the crucible under specific conditions before the growth of the silicon carbide crystal, the incorporation of the bulk of carbon into the silicon carbide crystal could be suppressed. Accordingly, silicon carbide substrate 100 with a reduced area density of voids can be obtained.

In a silicon carbide substrate 100 according to the present embodiment, one or more first voids 10 are present in a first main surface 1. An area density of first voids 10 is less than 0.9/cm². When viewed in a direction perpendicular to first main surface 1, first void 10 has a width of 10 μm or more and 100 μm or less. When viewed in a direction parallel to first main surface 1, the width of first void 10 increases from first main surface 1 toward a second main surface 2. When viewed in the direction parallel to first main surface 1, first void 10 has a depth smaller than a thickness of silicon carbide substrate 100. First main surface 1 is a carbon plane, or a plane inclined at an off angle θ of 8° or less relative to the carbon plane.

A silicon carbide substrate 100 according to the present embodiment has a first main surface 1 and a second main surface 2 opposite to first main surface 1. One or more first voids 10 are present in first main surface 1, and one or more second voids 20 are present in second main surface 2. An area density of second voids 20 is less than 0.9/cm². When viewed in a direction perpendicular to first main surface 1, each of first void 10 and second void 20 has a width of 10 μm or more and 100 μm or less.

When viewed in a direction parallel to first main surface 1, the width of each of first void 10 and second void 20 increases from first main surface 1 toward second main surface 2. When viewed in the direction parallel to first main surface 1, each of first void 10 and second void 20 has a depth smaller than a thickness of silicon carbide substrate 100. Second main surface 2 is a silicon plane, or a plane inclined at an off angle θ of 8° or less relative to the silicon plane.

When silicon carbide semiconductor device 400 is manufactured using silicon carbide substrate 100 described above, the yield of silicon carbide semiconductor device 400 can be improved.

In silicon carbide substrate 100 according to the present embodiment, when first main surface 1 is divided into a plurality of square regions 30, each of which is 5 mm on a side, the plurality of square regions 30 may be formed by a first region 31 where an area density of threading screw dislocations 4 is 3000/cm² or more, a second region 32 where the area density of threading screw dislocations 4 is 1000/cm² or more and less than 3000/cm², and a third region 33 where the area density of threading screw dislocations 4 is less than 1000/cm². The ratio of an area of first region 31 to a total area of first region 31, second region 32 and third region 33 may be 1% or more and 10% or less. Accordingly, the yield of silicon carbide semiconductor device 400 can be further improved.

In silicon carbide substrate 100 according to the present embodiment, the ratio of the area of first region 31 to the total area of first region 31, second region 32 and third region 33 may be 5% or more. Accordingly, the yield of silicon carbide semiconductor device 400 can be further improved.

In silicon carbide substrate 100 according to the present embodiment, an area density of threading screw dislocations 4 in second main surface 2 may be 1500/cm² or less. Accordingly, the yield of silicon carbide semiconductor device 400 can be further improved.

In silicon carbide substrate 100 according to the present embodiment, ten or more and twenty or less first carbon inclusions 71 may be present in a first cuboid region 61 located at a distance of 50 μm or more and 200 μm or less from first main surface 1 toward second main surface 2. When viewed in the direction perpendicular to first main surface 1, a long side of first cuboid region 61 may have a length of 0.82 mm, and a short side of first cuboid region 61 may have a length of 0.7 mm. When viewed in the direction perpendicular to first main surface 1, first void 10 may overlap first cuboid region 61. When viewed in the direction perpendicular to first main surface 1, each of first carbon inclusions 71 may have a maximum length of 5 μm or more and 50 μm or less. Accordingly, the yield of silicon carbide semiconductor device 400 can be further improved.

In silicon carbide substrate 100 according to the present embodiment, three or more and less than ten second carbon inclusions 72 may be present in a second cuboid region 62 located at a distance of 50 μm or more and 200 μm or less from first main surface 1 toward second main surface 2. When viewed in the direction perpendicular to first main surface 1, a long side of second cuboid region 62 may have a length of 0.82 mm, and a short side of second cuboid region 62 may have a length of 0.7 mm. When viewed in the direction perpendicular to first main surface 1, an area density of threading screw dislocations 4 in a region of first main surface 1 that overlaps second cuboid region 62 may be 3000/cm² or more. When viewed in the direction perpendicular to first main surface 1, each of second carbon inclusions 72 may have a maximum length of 5 μm or more and 50 μm or less. Accordingly, the yield of silicon carbide semiconductor device 400 can be further improved.

In silicon carbide substrate 100 according to the present embodiment, first main surface 1 may have a diameter of 150 mm or more. Accordingly, when silicon carbide substrate 100 having the large diameter is used, the yield of silicon carbide semiconductor device 400 can be further improved.

### Example 1

### (Preparation of Samples)

First, silicon carbide substrates 100 were fabricated using manufacturing conditions according to Samples 1 to 7. A firing step was performed in the manufacturing conditions according to Samples 1 to 6. Specifically, crucible 130 and a graphite member in crucible 130 were fired using the temperature profile shown in FIG. 11B. Third temperature C3 in FIG. 11B was a firing temperature. The time from third time point T3 to fourth time point T4 was a firing time. The firing step was not performed in the manufacturing conditions according to Sample 7.

The firing temperature in the manufacturing conditions according to Samples 1 and 2 was 2800° C. The firing temperature in the manufacturing conditions according to Samples 3 to 6 was 3000° C. The firing time in the manufacturing conditions according to Samples 1 and 4 was 10 hours. The firing time in the manufacturing conditions according to Samples 2 and 5 was 30 hours. The firing time in the manufacturing conditions according to Sample 6 was 60 hours. The firing time in the manufacturing conditions according to Sample 3 was 0 minute.

Next, silicon carbide crystal 110 was manufactured using crucible 130. Silicon carbide source material 153 and seed substrate 150 were placed in crucible 130, as shown in FIG. 12. Silicon carbide crystal 110 was grown on seed substrate 150 by sublimation. After the growth of silicon carbide crystal 110 was completed, silicon carbide crystal 110 was sliced using a saw wire. Accordingly, silicon carbide substrate 100 was cut. Silicon carbide substrate 100 had first main surface 1 and second main surface 2. First main surface 1 was a plane inclined in an off direction relative to a carbon plane. The off direction was <11-20>. Off angle θ was 2°. Silicon carbide substrate 100 according to each of Samples 1 to 7 was prepared in this manner.

### (Measurement Method)

In silicon carbide substrate 100 according to each of Samples 1 to 7, the area density of first voids 10 was measured. Specifically, the number of first voids 10 exposed at first main surface 1 of silicon carbide substrate 100 was measured. First voids 10 were identified using an optical microscope. A bottomed hole having a width of 10 μm or more and 100 μm or less when viewed in the direction perpendicular to first main surface 1 and increasing in width from first main surface 1 toward second main surface 2 was identified as first void 10. A value determined by dividing the number of first voids 10 in a measurement region of first main surface 1 by the area of the measurement region of first main surface 1 was defined as the area density of first voids 10.

In silicon carbide substrate 100 according to each of Samples 1, 3, 5 and 7, the number of first carbon inclusions 71 below certain first void 10 was counted. Specifically, the number of first carbon inclusions 71 was visually counted in a region where first void 10 is located at first main surface 1, while the focus of the microscope was shifted by a measurement depth from first main surface 1 toward second main surface 2 of silicon carbide substrate 100. The measurement depth was 100 μm. The long side of the measurement region had a length of 0.21 mm. The short side of the measurement region had a length of 0.18 mm.

### (Measurement Results)

TABLE 1

| | | | | | First carbon inclusions below certain | |
|---|---|---|---|---|---|---|
| | | Firing | Firing | Area density | first void | |
| | Firing | temperature | time | of first voids | Measurement | Number of first |
| | step | (° C.) | (hour) | (/cm²) | depth (μm) | carbon inclusions |
| Sample 1 | Performed | 2800 | 10 | 0.55 | 100 | 6 |
| Sample 2 | Performed | 2800 | 30 | 0.42 | — | — |
| Sample 3 | Performed | 3000 | 0 | 0.21 | 100 | 3 |
| Sample 4 | Performed | 3000 | 10 | 0.09 | — | — |
| Sample 5 | Performed | 3000 | 30 | 0.05 | 100 | 2 |
| Sample 6 | Performed | 3000 | 60 | 0.04 | — | — |
| Sample 7 | Not | — | — | 0.90 | 100 | 9 |
| | performed | | | | | |

Table 1 shows the area density of first voids 10 in silicon carbide substrate 100 according to each of Samples 1 to 7. As shown in Table 1, the area density of first voids 10 in silicon carbide substrate 100 according to each of Samples 1 to 6 was lower than the area density of first voids 10 in silicon carbide substrate 100 according to Sample 7. Accordingly, it was confirmed that the area density of first voids 10 could be reduced by performing the firing step. As the firing time became longer, the area density of first voids 10 became lower, when compared at the same firing temperature.

As the firing temperature became higher, the area density of first voids 10 became lower, when compared at the same firing time. In silicon carbide substrate 100 according to each of Samples 1, 3, 5 and 7, the number of first carbon inclusions 71 was six, three, two and nine, respectively.

### Example 2

### (Measurement Method)

In silicon carbide substrate 100 according to each of Samples 4 and 7, first regions 31, second regions 32, and third regions 33 were identified. Each of first regions 31 was a region where the area density of threading screw dislocations 4 was 3000/cm² or more. Each of second regions 32 was a region where the area density of threading screw dislocations 4 was 1000/cm² or more and less than 3000/cm². Each of third regions 33 was a region where the area density of threading screw dislocations 4 was less than 1000/cm².

The ratio of the area of first regions 31 to the total area of first regions 31, second regions 32 and third regions 33 (first region ratio), the ratio of the area of second regions 32 to the total area of first regions 31, second regions 32 and third regions 33 (second region ratio), and the ratio of the area of third regions 33 to the total area of first regions 31, second regions 32 and third regions 33 (third region ratio) were measured. The area density of threading screw dislocations 4 was measured in second main surface 2.

The area density of threading screw dislocations 4 was measured using molten potassium hydroxide (KOH). Each observed region for etch pits was 0.82 mm×0.70 mm. The observed regions had a pitch of 5 mm. The number of etch pits caused by threading screw dislocations 4 was measured in all observed regions. A value determined by dividing the total number of the etch pits in all observed regions by the total area of the observed regions was defined as the area density of threading screw dislocations 4 in second main surface 2. The temperature of the KOH melt was about 500° C. or more and 550° C. or less. The etching time was about 5 minutes or more and 10 minutes or less.

### (Measurement Results)

TABLE 2

| | | | | Area density of |
|---|---|---|---|---|
| | First | Second | Third | threading screw |
| | region | region | region | dislocations in |
| | ratio | ratio | ratio | second main |
| | (%) | (%) | (%) | surface (/cm²) |
| Sample 4 | 4.0 | 67.7 | 28.3 | 1300 |
| Sample 7 | 17.3 | 51.6 | 31.1 | 2000 |

Table 2 shows the first region ratio, the second region ratio, the third region ratio, and the area density of threading screw dislocations 4 in second main surface 2. As shown in Table 2, the first region ratio in silicon carbide substrate 100 according to Sample 4 was lower than the first region ratio in silicon carbide substrate 100 according to Sample 7. Accordingly, it was confirmed that the first region ratio could be reduced by performing the firing step. The area density of threading screw dislocations 4 in second main surface 2 of silicon carbide substrate 100 according to Sample 4 was lower than the area density of threading screw dislocations 4 in second main surface 2 of silicon carbide substrate 100 according to Sample 7. Accordingly, it was confirmed that the area density of threading screw dislocations 4 in second main surface 2 could be reduced by performing the firing step.

The present disclosure includes embodiments set out below.

### (Additional Aspect 1)

A silicon carbide substrate having a first main surface and a second main surface opposite to the first main surface, wherein
one or more first voids are present in the first main surface,
an area density of the first voids is less than 0.9/cm²,
when viewed in a direction perpendicular to the first main surface, the first void has a width of 10 μm or more and 100 μm or less,
when viewed in a direction parallel to the first main surface, the width of the first void increases from the first main surface toward the second main surface,
when viewed in the direction parallel to the first main surface, the first void has a depth smaller than a thickness of the silicon carbide substrate, and
the first main surface is a carbon plane, or a plane inclined at an off angle of 8° or less relative to the carbon plane.

### (Additional Aspect 2)

A silicon carbide substrate having a first main surface and a second main surface opposite to the first main surface, wherein
one or more first voids are present in the first main surface, and one or more second voids are present in the second main surface,
an area density of the second voids is less than 0.9/cm²,
when viewed in a direction perpendicular to the first main surface, each of the first void and the second void has a width of 10 μm or more and 100 μm or less,
when viewed in a direction parallel to the first main surface, the width of each of the first void and the second void increases from the first main surface toward the second main surface,
when viewed in the direction parallel to the first main surface, each of the first void and the second void has a depth smaller than a thickness of the silicon carbide substrate, and
the second main surface is a silicon plane, or a plane inclined at an off angle of 8° or less relative to the silicon plane.

### (Additional Aspect 3)

The silicon carbide substrate according to Additional Aspect 1 or 2, wherein
when the first main surface is divided into a plurality of square regions, each of which is 5 mm on a side, the plurality of square regions are formed by a first region where an area density of threading screw dislocations is 3000/cm² or more, a second region where the area density of threading screw dislocations is 1000/cm² or more and less than 3000/cm², and a third region where the area density of threading screw dislocations is less than 1000/cm², and
a ratio of an area of the first region to a total area of the first region, the second region and the third region is 1% or more and 10% or less.

### (Additional Aspect 4)

The silicon carbide substrate according to Additional Aspect 3, wherein the ratio of the area of the first region to the total area of the first region, the second region and the third region is 5% or more.

### (Additional Aspect 5)

The silicon carbide substrate according to Additional Aspect 1 or 2, wherein an area density of threading screw dislocations in the second main surface is 1500/cm² or less.

### (Additional Aspect 6)

The silicon carbide substrate according to Additional Aspect 1 or 2, wherein
ten or more and twenty or less first carbon inclusions are present in a first cuboid region of the silicon carbide substrate,
in the direction perpendicular to the first main surface, a distance from the first main surface to an upper end surface of the first cuboid region is 50 μm, and a distance from the first main surface to a lower end surface of the first cuboid region is 200 μm,
when viewed in the direction perpendicular to the first main surface, a long side of the first cuboid region has a length of 0.82 mm, and a short side of the first cuboid region has a length of 0.7 mm,
when viewed in the direction perpendicular to the first main surface, the first void overlaps the first cuboid region, and
when viewed in the direction perpendicular to the first main surface, each of the first carbon inclusions has a maximum length of 5 μm or more and 50 μm or less.

### (Additional Aspect 7)

The silicon carbide substrate according to Additional Aspect 1 or 2, wherein
three or more and less than ten second carbon inclusions are present in a second cuboid region of the silicon carbide substrate,
in the direction perpendicular to the first main surface, a distance from the first main surface to an upper end surface of the second cuboid region is 50 μm, and a distance from the first main surface to a lower end surface of the second cuboid region is 200 μm,
when viewed in the direction perpendicular to the first main surface, a long side of the second cuboid region has a length of 0.82 mm, and a short side of the second cuboid region has a length of 0.7 mm,
when viewed in the direction perpendicular to the first main surface, an area density of threading screw dislocations in a region of the first main surface that overlaps the second cuboid region is 3000/cm² or more, and
when viewed in the direction perpendicular to the first main surface, each of the second carbon inclusions has a maximum length of 5 μm or more and 50 μm or less.

### (Additional Aspect 8)

The silicon carbide substrate according to Additional Aspect 1 or 2, wherein the first main surface has a diameter of 150 mm or more.

### (Additional Aspect 9)

The silicon carbide substrate according to Additional Aspect 1 or 2, wherein the first main surface is a plane inclined at an off angle of 1° or more and 4° or less relative to the carbon plane.

### (Additional Aspect 10)

A silicon carbide epitaxial substrate comprising:
the silicon carbide substrate according to Additional Aspect 1 or 2; and
a silicon carbide epitaxial layer provided on the silicon carbide substrate.

### (Additional Aspect 11)

A method of manufacturing a silicon carbide semiconductor device, the method comprising:
preparing the silicon carbide epitaxial substrate according to Additional Aspect 10; and
processing the silicon carbide epitaxial substrate.

It should be understood that the embodiments and examples disclosed herein are illustrative and non-restrictive in every respect. The scope of the present invention is defined by the terms of the claims, rather than the description above, and is intended to include any modifications within the meaning and scope equivalent to the terms of the claims.

### REFERENCE SIGNS LIST

1 first main surface; 2 second main surface; 3 third main surface; 4 threading screw dislocation; 7 orientation flat portion; 8 arc-shaped portion; 9 outer circumferential side surface; 10 first void; 11 first opening; 12 first side surface portion; 13 first bottom portion; 14 third void; 15 silicon carbide region; 20 second void; 21 second opening; 22 second side surface portion; 23 second bottom portion; 30 square region; 31 first region; 32 second region; 33 third region; 41 buffer layer; 42 drift layer; 53 side wall surface; 54 bottom wall surface; 56 trench; 60 silicon carbide epitaxial layer; 61 first cuboid region; 62 second cuboid region; 71 first carbon inclusion; 72 second carbon inclusion; 100 silicon carbide substrate; 101 first direction; 102 second direction; 103 third direction; 110 silicon carbide crystal; 113 body region; 114 source region; 115 gate insulating film; 116 source electrode; 117 mask; 118 contact region; 119 source interconnection; 123 drain electrode; 126 interlayer insulating film; 127 gate electrode; 130 crucible; 131 lid portion; 132 source material housing portion; 141 first resistive heater; 142 second resistive heater; 143 third resistive heater; 150 seed substrate; 151 growth surface; 152 attachment surface; 153 silicon carbide source material; 200 silicon carbide epitaxial substrate; 300 manufacturing apparatus; 400 silicon carbide semiconductor device; A1 first width; A2 second width; B1 first depth; B2 second depth; C1 first temperature; C2 second temperature; C3 third temperature; D11, D21 first distance; D12, D22 second distance; D13, D23 third distance; E1 thickness; F1, F2 maximum length; L11, L21 first length; L12, L22 second length; T1 first time point; T2 second time point; T3 third time point; T4 fourth time point; W1 diameter; θ off angle.

1. A silicon carbide substrate having a first main surface and a second main surface opposite to the first main surface, wherein
one or more first voids are present in the first main surface,
an area density of the first voids is less than 0.9/cm²,
when viewed in a direction perpendicular to the first main surface, the first void has a width of 10 μm or more and 100 μm or less,
when viewed in a direction parallel to the first main surface, the width of the first void increases from the first main surface toward the second main surface,
when viewed in the direction parallel to the first main surface, the first void has a depth smaller than a thickness of the silicon carbide substrate, and
the first main surface is a carbon plane, or a plane inclined at an off angle of 8° or less relative to the carbon plane.

2. A silicon carbide substrate having a first main surface and a second main surface opposite to the first main surface, wherein
one or more first voids are present in the first main surface, and one or more second voids are present in the second main surface,
an area density of the second voids is less than 0.9/cm²,
when viewed in a direction perpendicular to the first main surface, each of the first void and the second void has a width of 10 μm or more and 100 μm or less,
when viewed in a direction parallel to the first main surface, the width of each of the first void and the second void increases from the first main surface toward the second main surface,
when viewed in the direction parallel to the first main surface, each of the first void and the second void has a depth smaller than a thickness of the silicon carbide substrate, and
the second main surface is a silicon plane, or a plane inclined at an off angle of 8° or less relative to the silicon plane.

3. The silicon carbide substrate according to claim 1, wherein
when the first main surface is divided into a plurality of square regions, each of which is 5 mm on a side, the plurality of square regions are formed by a first region where an area density of threading screw dislocations is 3000/cm² or more, a second region where the area density of threading screw dislocations is 1000/cm² or more and less than 3000/cm², and a third region where the area density of threading screw dislocations is less than 1000/cm², and
a ratio of an area of the first region to a total area of the first region, the second region and the third region is 1% or more and 10% or less.

4. The silicon carbide substrate according to claim 3, wherein the ratio of the area of the first region to the total area of the first region, the second region and the third region is 5% or more.

5. The silicon carbide substrate according to claim 1, wherein an area density of threading screw dislocations in the second main surface is 1500/cm² or less.

6. The silicon carbide substrate according to claim 1, wherein
ten or more and twenty or less first carbon inclusions are present in a first cuboid region of the silicon carbide substrate,
in the direction perpendicular to the first main surface, a distance from the first main surface to an upper end surface of the first cuboid region is 50 μm, and a distance from the first main surface to a lower end surface of the first cuboid region is 200 μm,
when viewed in the direction perpendicular to the first main surface, a long side of the first cuboid region has a length of 0.82 mm, and a short side of the first cuboid region has a length of 0.7 mm,
when viewed in the direction perpendicular to the first main surface, the first void overlaps the first cuboid region, and
when viewed in the direction perpendicular to the first main surface, each of the first carbon inclusions has a maximum length of 5 μm or more and 50 μm or less.

7. The silicon carbide substrate according to claim 1, wherein
three or more and less than ten second carbon inclusions are present in a second cuboid region of the silicon carbide substrate,
in the direction perpendicular to the first main surface, a distance from the first main surface to an upper end surface of the second cuboid region is 50 μm, and a distance from the first main surface to a lower end surface of the second cuboid region is 200 μm,
when viewed in the direction perpendicular to the first main surface, a long side of the second cuboid region has a length of 0.82 mm, and a short side of the second cuboid region has a length of 0.7 mm,
when viewed in the direction perpendicular to the first main surface, an area density of threading screw dislocations in a region of the first main surface that overlaps the second cuboid region is 3000/cm² or more, and
when viewed in the direction perpendicular to the first main surface, each of the second carbon inclusions has a maximum length of 5 μm or more and 50 μm or less.

8. The silicon carbide substrate according to claim 1, wherein the first main surface has a diameter of 150 mm or more.

9. The silicon carbide substrate according to claim 1, wherein the first main surface is a plane inclined at an off angle of 1° or more and 4° or less relative to the carbon plane.

10. A silicon carbide epitaxial substrate comprising:
the silicon carbide substrate according to claim 1; and
a silicon carbide epitaxial layer provided on the silicon carbide substrate.

11. A method of manufacturing a silicon carbide semiconductor device, the method comprising:
preparing the silicon carbide epitaxial substrate according to claim 10; and
processing the silicon carbide epitaxial substrate.

12. The silicon carbide substrate according to claim 2, wherein
when the first main surface is divided into a plurality of square regions, each of which is 5 mm on a side, the plurality of square regions are formed by a first region where an area density of threading screw dislocations is 3000/cm² or more, a second region where the area density of threading screw dislocations is 1000/cm² or more and less than 3000/cm², and a third region where the area density of threading screw dislocations is less than 1000/cm², and
a ratio of an area of the first region to a total area of the first region, the second region and the third region is 1% or more and 10% or less.

13. The silicon carbide substrate according to claim 12, wherein the ratio of the area of the first region to the total area of the first region, the second region and the third region is 5% or more.

14. The silicon carbide substrate according to claim 2, wherein an area density of threading screw dislocations in the second main surface is 1500/cm² or less.

15. The silicon carbide substrate according to claim 2, wherein
ten or more and twenty or less first carbon inclusions are present in a first cuboid region of the silicon carbide substrate,
in the direction perpendicular to the first main surface, a distance from the first main surface to an upper end surface of the first cuboid region is 50 μm, and a distance from the first main surface to a lower end surface of the first cuboid region is 200 μm,
when viewed in the direction perpendicular to the first main surface, a long side of the first cuboid region has a length of 0.82 mm, and a short side of the first cuboid region has a length of 0.7 mm,
when viewed in the direction perpendicular to the first main surface, the first void overlaps the first cuboid region, and
when viewed in the direction perpendicular to the first main surface, each of the first carbon inclusions has a maximum length of 5 μm or more and 50 μm or less.

16. The silicon carbide substrate according to claim 2, wherein
three or more and less than ten second carbon inclusions are present in a second cuboid region of the silicon carbide substrate,
in the direction perpendicular to the first main surface, a distance from the first main surface to an upper end surface of the second cuboid region is 50 μm, and a distance from the first main surface to a lower end surface of the second cuboid region is 200 μm,
when viewed in the direction perpendicular to the first main surface, a long side of the second cuboid region has a length of 0.82 mm, and a short side of the second cuboid region has a length of 0.7 mm,
when viewed in the direction perpendicular to the first main surface, an area density of threading screw dislocations in a region of the first main surface that overlaps the second cuboid region is 3000/cm² or more, and
when viewed in the direction perpendicular to the first main surface, each of the second carbon inclusions has a maximum length of 5 μm or more and 50 μm or less.

17. The silicon carbide substrate according to claim 2, wherein the first main surface has a diameter of 150 mm or more.

18. The silicon carbide substrate according to claim 2, wherein the first main surface is a plane inclined at an off angle of 1° or more and 4° or less relative to the carbon plane.

19. A silicon carbide epitaxial substrate comprising:
the silicon carbide substrate according to claim 2; and
a silicon carbide epitaxial layer provided on the silicon carbide substrate.

20. A method of manufacturing a silicon carbide semiconductor device, the method comprising:
preparing the silicon carbide epitaxial substrate according to claim 19; and
processing the silicon carbide epitaxial substrate.
